(19) United States
(12) Patent Application Publication
(10) Pub. No.: US 2010/0068828 A1
(43) Pub. Date: Mar. 18, 2010

(54) METHOD OF FORMING A STRUCTURE HAVING A GIANT RESISTANCE ANISOTROPY OR LOW-K DIELECTRIC

(76) Inventors: Shawn Thomas, Gilbert, AZ (US); Steven Smith, Gilbert, AZ (US); Yi Wei, Chandler, AZ (US)

Correspondence Address: MOTOROLA, INC., 1303 EAST ALGONQUIN ROAD, IL01/3RD, SCHAUMBURG, IL, 60196, US

(21) Appl. No.: 11/584,078

(22) Filed: Oct. 20, 2006

Related U.S. Application Data
(60) Provisional application No. 60/749,310, filed on Dec. 8, 2005.

(51) Int. Cl. H01L 21/3205

(52) U.S. Cl. 438/3; 438/669; 257/E21.294; 977/842

(57) ABSTRACT

A method is provided involving the growth of carbon nanotubes to provide giant resistance anisotropy or a low-k dielectric. The method comprises growing a plurality of one-dimensional nanostructures (18) orthogonal to a first conductive layer (14). A dielectric material (22, 32, 60) is formed covering the plurality of one-dimensional nanostructures and then etched to remove a portion of the dielectric material (22, 32, 60) to expose the ends (24, 34, 68) of the one-dimensional nanostructures (18). A second conductive layer (26, 36, 84) is formed over the dielectric material (22, 32, 60) to make contact with the ends (24, 34, 68) of the one-dimensional nanostructures (18). One or both of the first (14) and second (26, 36, 84) layers may be patterned for accessing individual or groups of the one-dimensional nanostructures (18). In another exemplary embodiment, the one-dimensional nanostructures (18) may be removed prior to forming the second layer (84), thereby creating a high-k dielectric layer (32) between the first and second layers (14, 84).

### FIELD OF THE INVENTION

The present invention generally relates to one-dimensional nanostructures and more particularly to a method involving the growth of carbon nanotubes to provide giant resistance anisotropy or a low-k dielectric.

### BACKGROUND OF THE INVENTION

One-dimensional nanostructures, such as belts, rods, tubes and wires, have become the focus of intensive research with their own unique applications. One-dimensional nanostructures are model systems to investigate the dependence of electrical and thermal transport or mechanical properties as a function of size reduction. In contrast with zero-dimensional, e.g., quantum dots, and two-dimensional nanostructures, e.g., GaAs/AlGaAs superlattice, direct synthesis and growth of one-dimensional nanostructures has been relatively slow due to difficulties associated with controlling the chemical composition, dimensions, and morphology. Alternatively, various one-dimensional nanostructures have been fabricated using a number of advanced nanolithographic techniques, such as electron-beam (e-beam), focused-ion-beam (FIB) writing, and scanning probe.

Carbon nanotubes are one of the most important species of one-dimensional nanostructures. Carbon nanotubes are one of four unique crystalline structures for carbon, the other three being diamond, graphite, and fullerene. In particular, carbon nanotubes refer to a helical tubular structure grown with a single wall (single-walled nanotubes) or multiple wall (multi-walled nanotubes). These types of structures are obtained by rolling a sheet formed of a plurality of hexagons. The sheet is formed by combining each carbon atom thereof with three neighboring carbon atoms to form a helical tube. Carbon nanotubes typically have a diameter on the order of a fraction of a nanometer to a few hundred nanometers. As used herein, a “carbon nanotube” is any elongated carbon structure.

Another class of one-dimensional nanostructures is nanowires. Nanowires of inorganic materials have been grown from metal (e.g., Ag, and Au), elemental semiconductors (e.g., Si, and Ge), III-V semiconductors (e.g., GaAs, GaN, GaP, InAs, and InP), II-VI semiconductors (e.g., CdS, CdSe, ZnS, and ZnSe) and oxides (e.g., SiO₂ and ZnO). Similar to carbon nanotubes, inorganic nanowires can be synthesized with various diameters and length, depending on the synthesis technique and/or desired application needs.

Both carbon nanotubes and inorganic nanowires have been demonstrated as field effect transistors (FETs) and other basic components in nanoscale electronics such as p-n junctions, bipolar junction transistors, inverters, etc. The motivation behind the development of such nanoscale components is that “bottom-up” approach to nanoelectronics has the potential to go beyond the limits of the traditional “top-down” manufacturing techniques.

Unlike other inorganic one-dimensional nanostructures, carbon nanotubes can function as either a conductor, or a semiconductor, according to the chirality and the diameter of the helical tubes. With metallic-like nanotubes, a one-dimensional carbon-based structure can conduct a current at room temperature with essentially no resistance. Further, electrons can be considered as moving freely through the structure, so that metallic-like nanotubes can be used as ideal interconnects. When semiconductor nanotubes are connected to two metal electrodes, the structure can function as a field effect transistor wherein the nanotubes can be switched from a conducting to an insulating state by applying a voltage to a gate electrode. Therefore, carbon nanotubes are potential building blocks for nanoelectronic and sensor devices because of their unique structural, physical, and chemical properties.

Resistance anisotropy in materials or thin films occurs when the resistance in one direction (e.g longitudinal) is different than the resistance in another (e.g. horizontal). Examples of this have been reported in the literature with directionally aligned carbon nanotube mats. The shortcoming of the previously reported approaches of resistance anisotropy in carbon nanotube films is that the ratio of anisotropy is limited to the order of 10:1. For applications such as memory devices, this level of anisotropy is too low to enable complete isolation between adjacent memory cells.

Accordingly, it is desirable to provide a method involving the growth of carbon nanotubes to provide giant resistance anisotropy or a low-k dielectric. Furthermore, other desirable features and characteristics of the present invention will become apparent from the subsequent detailed description of the invention and the appended claims, taken in conjunction with the accompanying drawings and this background of the invention.

### BRIEF SUMMARY OF THE INVENTION

A method is provided involving the growth of carbon nanotubes to provide giant resistance anisotropy or a low-k dielectric. The method comprises growing a plurality of one-dimensional nanostructures orthogonal to a first conductive layer. A dielectric material is formed covering the plurality of one-dimensional nanostructures and then etched to remove a portion of the dielectric material to expose the ends of the one-dimensional nanostructures. In one embodiment, a second conductive layer is formed over the dielectric material to make contact with the ends of the one-dimensional nanostructures. One or both of the first and second layers may be patterned for accessing individual or groups of the one-dimensional nanostructures. In another exemplary embodiment, the one-dimensional nanostructures may be removed prior to forming an overlying layer, thereby creating a low-k dielectric layer between the first and second layers.

### BRIEF DESCRIPTION OF THE DRAWINGS

The present invention will hereinafter be described in conjunction with the following drawing figures, wherein like numerals denote like elements, and

FIG. 1 is a partial prospective view of a plurality of one-dimensional nanostructures grown above a substrate;

FIGS. 2-4 are partial cross-sectional views of a first exemplary embodiment;

FIGS. 5-6 are partial cross-sectional views of a second exemplary embodiment;

FIG. 7 is a partial cross-sectional views of third and fourth exemplary embodiments;

FIGS. 8-10 are partial cross-sectional views of a fifth exemplary embodiment;

FIG. 11 is a partial cross-sectional view of a sixth exemplary embodiment; and

FIG. 12 is a partial cross-sectional view of a seventh exemplary embodiment.

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

One-dimensional nanostructures such as nanotubes and nanowires show promise for the development of molecular-scale sensors, resonators, field emission displays, and logic/memory elements. One-dimensional nanostructures are herein defined as a material having a high aspect ratio of greater than 10 to 1 (length to diameter).

A dense array of one-dimensional nanostructures are grown by chemical vapor deposition (CVD) techniques, preferably by plasma enhanced chemical vapor deposition (PECVD), and are vertically aligned (orthogonal) with respect to a substrate. The one-dimensional nanostructures are then coated with a dielectric material, e.g., an oxide or nitride, using PECVD. The dielectric material isolates each one-dimensional nanostructure from neighboring one-dimensional nanostructures, thereby creating a high resistance anisotropy. One-dimensional nanostructures can be highly conductive, even exceeding the conductivity of copper, and have a higher conductivity along its length rather than its diameter. And since the one-dimensional nanostructures are within the coating of dielectric material, the conduction in the vertical direction (along the length of the one-dimensional nanostructure) is much larger than laterally through the dielectric material. By tailoring the density of the one-dimensional nanostructures and the thickness of the dielectric material, the resistance anisotropy can be tuned for the specific application. This method provides lateral isolation without having to utilize lithography to create a physical separation (isolation). This has the advantage that the blanket film can be used to make contact to an electrical contact with the pitch between electrical contacts only limited by the diameter of the electrical probe. This may be on the order of a few nanometers (1.0 to 3.0 nm), whereas a lithographically limited contact may only be on the order of ten's of nanometers. Additionally, this method allows contact to be made in a single step/process chamber while a lithographic approach uses multiple steps, e.g., deposition of a blanket film lithographic patterning, and etch for isolation.

A second exemplary embodiment comprises coating the one-dimensional nanostructures with a dielectric material and performing a blanket etch or planarizing process, e.g., a wet chemical etch, dry plasma etch or a chemical-mechanical polish (CMP), to expose the tip of the one-dimensional nanostructures. A subsequent etch, e.g., an oxygen plasma etch or a wet chemical etch, is performed to remove the one-dimensional nanostructures within the dielectric material, resulting in hollow/air-filled dielectric tubes. A capping layer of dielectric material is formed, e.g., deposited, sputtered, or evaporated, on top of the hollow dielectric tubes to cap the top of the tubes. These steps result in a dielectric material that has a dielectric constant lower than a pure, bulk dielectric material. By tailoring the density of the one-dimensional nanostructures and the thickness of the dielectric material, the density of the pore filled dielectric can be modulated, thus tailoring the k-value of the low-k dielectric.

In another embodiment, the hollow dielectric tubes can be filled with a second material of lower k-value (e.g. polymer, silica, etc) than the encapsulating dielectric material to tune the dielectric constant of the composite and/or aid in the structural integrity of the film.

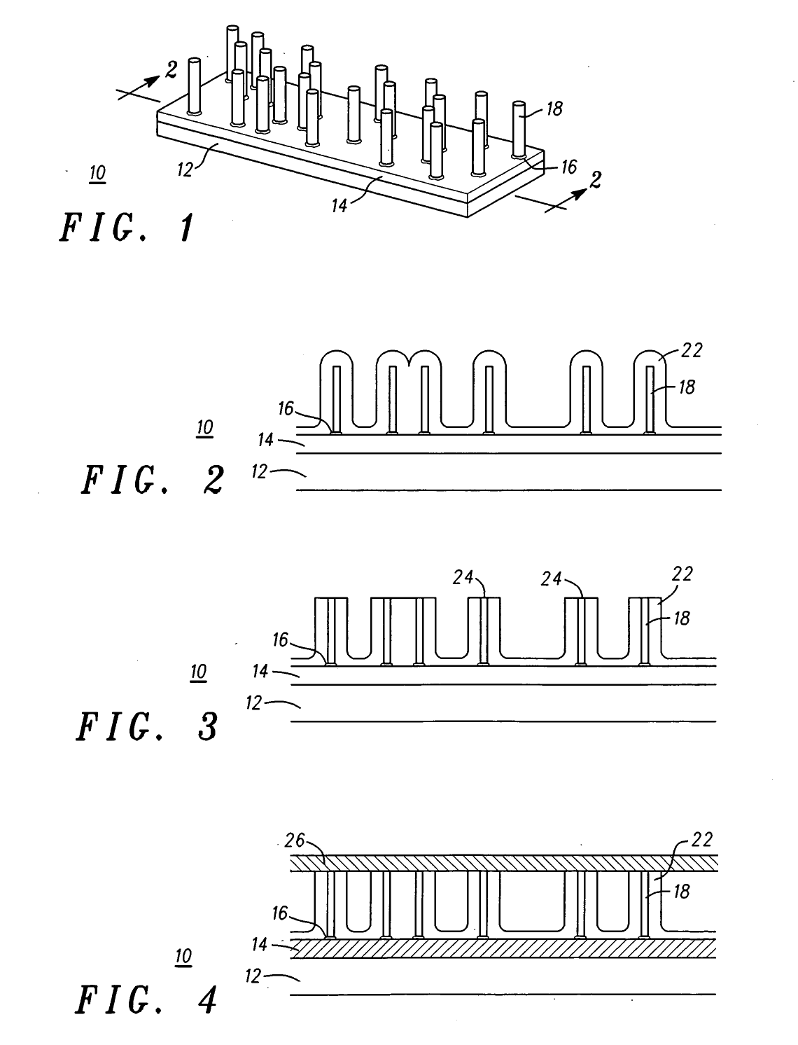

Though the present invention may be applied to nanostructures as defined herein, the exemplary embodiment illustrates the treatment of carbon nanotubes; however, the invention should not be limited to carbon nanotubes. Referring now to FIG. 1, illustrated in a simplified perspective view is an assembled structure utilized for growth of carbon nanotubes according to an exemplary embodiment of the present invention. More specifically, a structure 10 includes a substrate 12 comprising a semiconductor material that provides structure for growing one-dimensional nanostructures. The substrate 12 comprises any semiconductor material well known in the art, for example, silicon (Si), gallium arsenide (GaAs), germanium (Ge), silicon carbide (SiC), indium arsenide (InAs), or the like. Alternatively, the substrate 12 may be formed as an insulating material, such as glass, plastic, ceramic, or any dielectric material that would provide insulating properties.

An optional layer 14 is preferably formed on the substrate by deposition, but may be formed in any manner. The layer 14 may be either non-conductive or conductive, depending on the application as subsequently discussed. In the case of the layer 14 being non-conductive, the possible materials to be used can include, but not limited to, dielectrics (e.g. SiO2, SiN), or phase-change materials (e.g. ferroelectrics, piezoelectrics, ovonic materials, etc). In the case of the layer 14 being conductive, the layer 14 may be patterned by using any form of lithography, for example, photolithography, electron beam lithography, and imprint lithography. The layer 14 may comprise any conductive material (e.g semiconductor, metal, optical or optoelectronic element), but preferably comprises a thin layer of gold. In some embodiments, the conductive layer 14 may comprise a highly doped semiconductor material. The conductive layer 14 comprises a thickness in the range of 1 nanometer to 5000 nanometers.

A catalyst layer, comprising or example, nanoparticles 16, is formed over the conductive layer 14 to initiate the growth of carbon nanotubes 18. It should be understood that the carbon nanotubes 18 may be formed in any manner known or hereinafter developed. After the catalyst layer 16 is formed, the carbon nanotubes 18 are then grown from the catalyst layer 16 in a manner known to those skilled in the art, e.g., applying a gas comprising hydrogen and carbon for carbon nanotube growth. Although only a small number of carbon nanotubes 18 are shown, those skilled in the art understand that any number of carbon nanotubes 18 could be formed.

Referring to FIG. 2 and in accordance with a first exemplary embodiment, a conformal coating of a dielectric material 22 is formed over and around each of the carbon nanotubes 18. While the preferred material for the dielectric material 22 is an oxide such as silicon oxide, any dielectric material may be used. Other examples of the dielectric material 22 include polysilicon, ferroelectrics, high-k dielectrics (e.g. HfO2, TaₓO_{y}, AlₓO_{y}, etc), and nitrides such as silicon nitride.

A chemical-mechanical polish or a dry or wet etch (FIG. 3) is performed to expose the ends 24 of the carbon nanotubes 18. A conductive layer 26, which may be a blanket layer or a patterned layer, is formed (FIG. 4) on the dielectric layer 22 and the ends 24. Alternatively, a conductive layer may be omitted and direct probing of the exposed carbon nanotube using a probing element (e.g. atomic force microsope, scanning tunneling microscope, or similar fine tip structure) can be performed. Electrical current may flow through the carbon nanotubes 18 between the conductive layer 14 and the conductive layer 26 for the applications to be discussed hereinafter. Furthermore, one or both of the layers 14, 26 may be patterned to form traces for accessing individual or groups of the one-dimensional nanostructures 18.

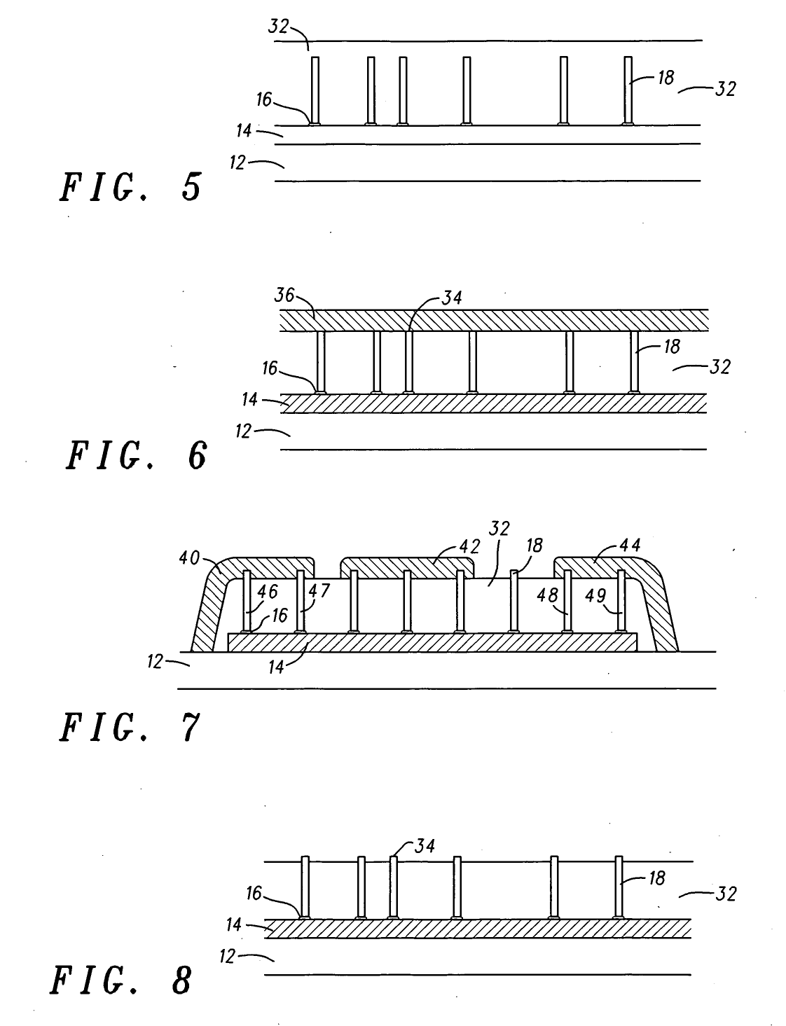

Referring to FIGS. 5 and 6, a second exemplary embodiment comprises depositing a blanket dielectric layer 32 over the layer 14 and the one-dimensional nanostructures 18. After etching to remove a portion of the blanket dielectric layer 32 to expose the ends 34 of the one-dimensional nanostructures 18, a conductive layer 36 is formed over the blanket dielectric layer and ends 34 of the one-dimensional nanostructures 18. As in the first exemplary embodiment, one or both of the layers 14 and 36 may be patterned for accessing individual or groups of the one-dimensional nanostructures 18.

A third exemplary embodiment, shown in FIG. 7, comprises the substrate 12, layer 14, one-dimensional nanostructures 18 and layer 32 as in the second exemplary embodiment. The layer 14 is conductive and patterned for making electrical contact with one end of the one-dimensional nanostructures 18. Conductive regions 40, 42, and 44 are formed using lithographic methods to contact ends of the one-dimensional nanostructures 18 opposed to the ends contacting the layer 14. Contact may be made from any one of the conductive regions 40, 42, and 44 to any one of the other conductive regions 40, 42 and 44 and the layer 14. For example, electrons may flow from conductive region 40 through one-dimensional nanostructures 46 and 47 through the conductive layer 14 to the one-dimensional nanostructures 48 and 49 to conductive region 44.

Alternatively and in a fourth exemplary embodiment, shown also in FIG. 7, the layer 14 is non-conductive. Contact may be made between any one of the conductive regions 40, 42, and 44. For example, electrons may flow from conductive region 40 through one-dimensional nanostructures 46 and 47 through the dielectric material 32 to the one-dimensional nanostructures 48 and 49.

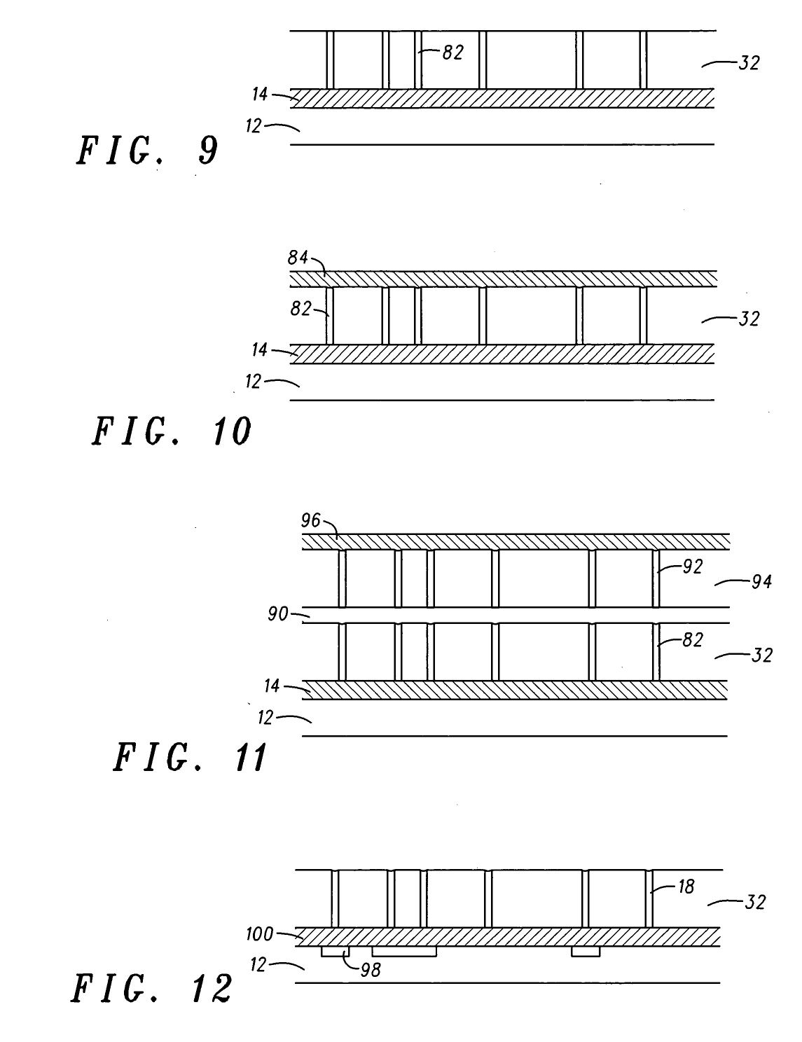

A fifth embodiment (FIGS. 8-10) comprises, after etching down to expose the ends 34 of the one-dimensional nanostructures 18 as in the second exemplary embodiment of FIG. 6, performing an etch, e.g., by a wet etch or an oxygen plasma etch, to remove the carbon nanotubes to define empty regions 82. A conductive layer 84 is then formed over the dielectric layer 32 (note that some of the conductive layer 84 may form within the regions 82, but should not reach to the conductive layer 14). This method provides a low-k dielectric region between the conductive layers 14 and 84.

A sixth embodiment (FIG. 11) comprises forming multiple layers of one-dimensional nanostructures 18 and 92. A non-conductive layer 90 is formed over the dielectric layer 32 and the one-dimensional nanostructures 18, and one-dimensional nanostructures are formed over the non-conductive layer 90. A dielectric material 94 is formed around the one-dimensional nanostructures 92. A conductive layer 94 is formed over the dielectric material 94 and the one-dimensional nanostructures 92.

Referring to FIG. 12, a seventh embodiment comprises conductive traces 98 formed within the substrate 12 and beneath the layer 100. Layer 100 comprises a phase change material, including but not limited to, Ag₁₁In₁₂Te₂₆Sb₅₁, Ge₂Sb₂Te₅ or Bi₂YO₄Cu₂Se₂. The one-dimensional nanostructures 18 may be probed, thereby changing the characteristics of the layer 100 due to the current flow from the one-dimensional nanostructure 18 to the conductive traces 98.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims.

1. A method comprising:
forming a substrate;
forming a first plurality of one-dimensional nanostructures over and orthogonal to the substrate;
forming a first dielectric material coating each of the first plurality of one-dimensional nanostructures, wherein the density of the one-dimensional nanostructures and the thickness of the dielectric material are tailored to tune the desired resistance anisotropy for a specific application; and
removing a portion of the first dielectric material to expose a portion of each of the first plurality of one-dimensional nanostructures.

2. The method of claim 1 further comprising forming a conductive material over the first dielectric material and making contact with each of the first plurality of one-dimensional nanostructures.

3. The method of claim 2 wherein the forming a substrate includes forming a conductive layer.

4. The method of claim 2 wherein the forming the conductive material comprises forming a patterned conductive material including a plurality of first traces, each of the first traces uniquely coupled to at least one of the one-dimensional nanostructures.

5. The method of claim 4 wherein the forming the substrate comprises forming a patterned conductive layer including a plurality of second traces, each of the second traces uniquely coupled to at least one of the one-dimensional nanostructures.

6. The method of claim 1 wherein the forming a dielectric material step comprises forming a conformal layer.

7. A method comprising:
forming a substrate;
forming a first plurality of one-dimensional nanostructures over and orthogonal to the substrate;
forming a first dielectric material coating each of the first plurality of one-dimensional nanostructures;
removing a portion of the first dielectric material to expose a portion of each of the first plurality of one-dimensional nanostructures;
forming a conductive material over the first dielectric material and making contact with each of the first plurality of one-dimensional nanostructures;
forming a second plurality of one-dimensional nanostructures over and orthogonal to the substrate, wherein the forming a first dielectric material includes forming a first dielectric material coating each of the second plurality of one-dimensional nanostructures and the removing step includes removing a portion of the first dielectric material to expose a portion of each of the second plurality of one-dimensional nanostructures; and
forming a first conductive region over the first dielectric material and making contact with the second plurality of one-dimensional nanostructures.

8. The method of claim 7 further comprising:
forming a third plurality of one-dimensional nanostructures over and orthogonal to the substrate, wherein the forming a first dielectric material includes forming a first dielectric material coating each of the third plurality of one-dimensional nanostructures and the removing step includes removing a portion of the first dielectric material to expose a portion of each of the third plurality of one-dimensional nanostructures; and
forming a second conductive region over the first dielectric material and making contact with the third plurality of one-dimensional nanostructures.

9. The method of claim 1 further comprising forming a non-conductive material over the first dielectric material and the one-dimensional nanostructures.

10. (canceled)

11. (canceled)

12. (canceled)

13. A method comprising:
forming a first layer;
forming a plurality of one-dimensional nanostructures orthogonal to the first layer, each one-dimensional nanostructure having first and second ends and a side, the first end being attached to the first layer;
forming a dielectric material coating the sides and over the second ends of each of the plurality of one-dimensional nanostructures, wherein the density of the plurality of one-dimensional nanostructures and the thickness of the dielectric material are tailored to tune the desired resistance anisotropy for a specific application;
removing a portion of the dielectric material to expose the second ends.

14. The method of claim 13 further comprising forming a second layer comprising a conductive material over the dielectric material and making contact with the one-dimensional nano structures.

15. The method of claim 14 wherein the forming a first layer comprises forming a first layer of a conductive material.

16. The method of claim 14 wherein the forming the second layer comprises forming a patterned second layer including a plurality of first traces, each of the first traces uniquely coupled to at least one of the one-dimensional nanostructures.

17. The method of claim 16 wherein the forming a first layer comprise forming a patterned conductive first layer including a plurality of second traces, each of the second traces uniquely coupled to at least one of the one-dimensional nanostructures.

18. (canceled)

19. The method of claim 13 wherein the first layer comprises a ferroelectric material, and further comprising at least one region of conductive material on a side of the first layer opposed to the plurality of one-dimensional nanostructures.

20. (canceled)

21. (canceled)
